(19) United States
(12) Patent Application Publication
(10) Pub. No.: US 2010/0275844 A1
(43) Pub. Date: Nov. 4, 2010

(54) DEPOSITION APPARATUS

(75) Inventors: Jeon-Ho Kim, Cheonan-si (KR); Young-hoon Kim, Cheonan-si (KR); Dae-Youn Kim, Daejeon (KR)

Correspondence Address: LEXYOUME IP GROUP, LLC, 5180 PARKSTONE DRIVE, SUITE 175, CHANTILLY, VA, 20151, US

(73) Assignee: ASM GENITECH KOREA LTD., Cheonan-si (KR)

(21) Appl. No.: 12/768,831

(22) Filed: Apr. 28, 2010

(30) Foreign Application Priority Data
Apr. 30, 2009 (KR) 10-2009-0038425

(51) Int. Cl. C23C 16/00

(52) U.S. Cl. 118/715

(57) ABSTRACT

In a deposition apparatus according to an embodiment of the present invention, a buffer unit is provided between a vaporizer and a reactor of a vaporization supply system to temporarily store source gas, thus, before and when the source gas is supplied to the reactor, the variations of the internal pressure of the vaporizer can be reduced to supply the constant amount of source gas of to reaction spaces, thereby depositing a thin film having a uniform thin-film thickness.

### CROSS-REFERENCE TO RELATED APPLICATION

This application claims priority to and the benefit of Korean Patent Application No. 10-2009-0038425 filed in the Korean Intellectual Property Office on Apr. 30, 2009, the entire contents of which are incorporated herein by reference.

### BACKGROUND OF THE INVENTION

(a) Field of the Invention

The present invention relates to a deposition apparatus. More specifically, the present invention relates to a deposition apparatus including a liquid and gas supply system for a thin film manufacturing process.

(b) Description of the Related Art

A liquid delivery system (LDS) has been widely known among methods for supplying source gases used in a process for manufacturing various thin films such as an oxide film or a metal film.

In general, a vaporization supply system has a liquid flow controller (LFC) controlling the flow of a liquid source and a vaporizer vaporizing the liquid source at high temperature and supplies vaporized source gas to a reactor by using and controlling a valve installed between the vaporizer and the reactor.

In the case of using the vaporization supply system, when the source gas is not supplied to the reactor in a state where the valve between the vaporizer and the reactor is closed, the source gas is accumulated between the vaporizer and the valve, thereby elevating the internal pressure of the vaporizer. Like this, when the valve is opened to supply the source gas to the reactor in a state where the internal pressure of the vaporizer increases, the internal pressure of the vaporizer rapidly decreases. As such, when the internal pressure of the vaporizer greatly varies, it is difficult to secure film reproducibility.

In particular, the reactor includes a plurality of reaction spaces, thus, in the case of multiple chamber depositions apparatuses sequentially supplying the source gas to the plurality of reaction spaces, since a supplying valve of the source gas is repetitively opened and closed, the internal pressure of the vaporizer may more greatly vary. As a result, the source gas may not constantly be supplied to the reaction spaces.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a deposition apparatus having an advantage of supplying source gas stably to reaction spaces by reducing the variations of the internal pressure of a vaporizer in a vaporization supply system.

An exemplary embodiment of the present invention provides a deposition apparatus that includes: a reactor; a liquid source unit storing a liquid source of source gas supplied to the reactor; a liquid source flow controller controlling the flow of the liquid source flowing into the vaporizer; a vaporizer vaporizing the liquid source supplied from the liquid source flow controller; and a buffer unit disposed between the reactor and the vaporizer.

The reactor may include a plurality of reaction spaces. The deposition apparatus may further include a source supplying valve disposed between the buffer unit and the reactor.

The source gas may be supplied from the vaporizer to the reactor when the source supplying valve is opened.

The source gas discharged from the vaporizer may be stored in the buffer unit when the source supplying valve is closed. The internal pressure of the vaporizer may be constant after the source gas starts to be supplied to the vaporizer.

According to an embodiment of the present invention, a buffer unit is provided between a vaporizer and a reactor of a vaporization supply system to temporarily store source gas, thus, before and when the source gas is supplied to the reactor, the variations of the internal pressure of the vaporizer can be reduced to supply constant amount of source gas to reaction spaces, thereby depositing a thin film having uniform thickness on a substrate.

### BRIEF DESCRIPTION OF THE DRAWINGS

FIG. 1 is a conceptual diagram schematically showing a deposition apparatus according to an embodiment of the present invention;

FIG. 2 is a graph showing the variations of the internal pressure of a vaporizer according to an experimental example of the present invention;

FIG. 3A and FIG. 3B are graphs showing a thickness for each position of a deposited thin film according an experimental example of the present invention; and

FIG. 4 is a graph showing thickness uniformity of a thin film deposited according an embodiment of the present invention.

### DETAILED DESCRIPTION OF THE EMBODIMENTS

The present invention will be described more fully hereinafter with reference to the accompanying drawings, in which exemplary embodiments of the invention are shown. As those skilled in the art would know, the described embodiments may be modified in various different ways, all without departing from the spirit or scope of the present invention.

In the drawings, the thickness of layers, films, panels, regions, etc., are a bit exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Hereinafter, a deposition apparatus according to an embodiment of the present invention will be described in detail with reference to the accompanying drawings.

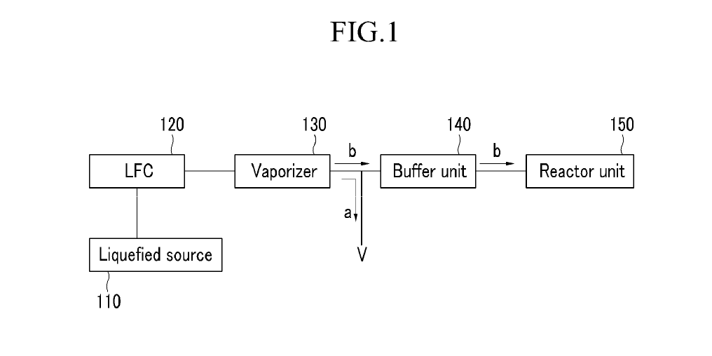

First, referring to FIG. 1, a deposition apparatus according to an embodiment of the present invention will be described. FIG. 1 is a block diagram schematically showing a deposition apparatus according to an embodiment of the present invention.

Referring to FIG. 1, the deposition apparatus according to the embodiment of the present invention includes a liquid source unit 110 where liquid source is stored, a flow controller 120 controlling the flow of the liquid source transferred from the liquid source unit 110, a vaporizer 130 vaporizing a liquid source supplied in an amount determined by the flow controller 120, a reactor 150 depositing a thin film by receiving source gas from the vaporizer 130, and a buffer unit 140 connected between the vaporizer 130 and the reactor 150. Although not shown, a source gas supplying valve (not shown) is disposed between the buffer unit 140 and the reactor 150.

Liquid source for forming a desired thin film is stored in the liquid source unit 110. The liquid source unit 110 is connected to the flow controller 120 and the flow controller 120 controls the flow of the liquid source supplied to the vaporizer 130 depending on the amount of source gas required to form the thin film. When the liquid source is supplied to the vaporizer 130 by the flow controlled by the flow controller 120, the vaporizer 130 converts the liquid source to gas by using high thermal energy. The source gas vaporized from the vaporizer 130 is supplied to the reactor by opening or closing the source gas supplying valve.

The deposition apparatus according to the embodiment of the present invention includes the buffer unit 140 connected between the vaporizer 130 and the reactor 150. The buffer unit 140 serves to temporarily store the source gas continuously supplied from the vaporizer 130 when the source gas supplying valve is changed from an opened state to a closed state. Accordingly, the source gas is accumulated in a pipe between the vaporizer 130 and the source gas supplying valve to thereby serve as a buffer role to prevent the pressure of the vaporizer 130 from varying during process in a reactor. In case of adding buffer unit 140 to the pipe between the vaporizer 130 and the source supplying valve, the internal pressure of the vaporizer 130 does not increase even in the case where the source gas supplying valve is changed from the opened state to the closed state due to the buffer unit 140, so the variation of the internal pressure of the vaporizer 130 is not large even in the case where the source gas supplying valve is again changed from the closed state to opened state. Accordingly, a constant amount of source gas may be stably supplied to the reactor 150 regardless of repetitive opening/closing operations of the source gas supplying valve to thereby deposit a thin film having good uniformity.

The reactor 150 of the deposition apparatus according to the embodiment of the present invention may include a plurality of reaction spaces. Therefore, when the same source gas is repetitively supplied to the plurality of reaction spaces in sequence, the source gas supplying valve is repetitively opened and closed in sequence. In this case, when the source gas supplying valve is changed from the opened state to the closed state, the buffer unit 140 temporarily stores the source gas supplied continuously from the vaporizer 130. As a result, the pipe between the vaporizer 130 and the source gas supplying valve is accumulated with source gas to thereby prevent the internal pressure of the vaporizer 130 from increasing. Accordingly, the constant amount of source gas may sequentially be stably supplied to the plurality of reaction spaces and thin films having the same and good uniformity may be deposited on a substrate regardless of the number of reaction spaces.

The buffer unit 140 preferably has a storage capacity enough to store predetermined amount of source gas and for example, may have a storage capacity of approximately 1 litter. The storage capacity of the buffer unit 140 may depend on structure or design of the deposition apparatus.

Therefore, referring to the experimental example, an effect of the deposition apparatus according to the embodiment of the present invention will be described hereinafter.

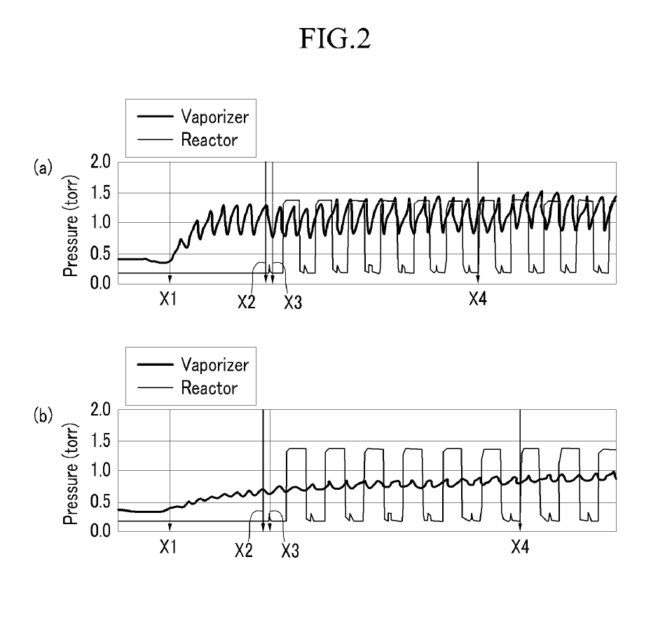

In this experimental example, the variations of the internal pressure of the deposition apparatus according to the embodiment of the present invention and the vaporizer of the deposition apparatus including the known vaporization supply system are measured. For this, the variation of the internal pressure of the vaporizer 130 is measured from a point where liquid source does not start to vaporize, to a point where the liquid source is supplied to the vaporizer 130 from the liquid source unit 110 and starts to vaporize, to a point where source gas is supplied to the reactor 150, with the source supplying valve being opened, to a point where the source gas is no more supplied to the reactor 150 by closing the source supplying valve. In this experimental example, the variations of the internal pressure of the vaporizer 130 are measured in two cases; (a) where the buffer unit 140 of the deposition apparatus is not included, and (b) where the buffer unit 140 is included like the deposition apparatus according to the embodiment of the present invention, All other conditions are the same except for whether or not the buffer unit 140 is included. The result of the experimental example is shown in FIG. 2. FIG. 2 is a graph showing the pressure variations of a vaporizer 130 and reactor 150 according to an experimental example of the present invention. In FIG. 2, a point where the liquid source starts to vaporize by being supplied to the vaporizer 130 from the liquid source unit 110 is marked with x1, a point where a process is started, the source gas supplying valve is opened, and the source gas is supplied to the reactor 150 is marked with x2, and a point where the source gas supplying valve is closed during the process and the source gas is not supplied to the reactor 150 is marked with x3.

Thereafter, a point where a reaction gas supplying valve is opened, thus, reaction gas is supplied to the reactor 150 is marked with x4.

Referring to FIG. 2, at point x1 where the source gas supplying process is started and the liquid source starts to vaporize in the vaporizer 130, and the internal pressures of the vaporizer 130 are almost equal to each other in both cases of (a) where the buffer unit 140 of the deposition apparatus is not included and (b) where the buffer unit 140 is included like the deposition apparatus according to the embodiment of the present invention. Thereafter, the internal pressure of the vaporizer 130 increases as the liquid source is vaporized. At this time, the range of pressure variation when the internal pressure of the vaporizer increases depends on whether or not the buffer unit 140 exists. In the case (a) where the buffer unit 140 is not included, the range of pressure variation is large up to the point x2 as shown in FIG. 2A, while in the case (b) where the buffer unit 140 is included, the range of pressure variation is small up to the time x2 as shown in FIG. 2B. At this time, the source gas vaporized by the vaporizer 130 is discharged to not the reactor 150 but a discharge path ‘v’ along a path ‘a’ shown in FIG. 1.

When the internal pressure of the vaporizer 130 reaches a level having enough amount of vapor to be supplied to the reactor, the source gas supplying valve is opened. As a result, the source gas starts to be supplied to the reactor 150 along a path ‘b’ shown in FIG. 1. Thereafter, the source gas supplying valve is repetitively opened and closed while the process is performed. At this time, a point where the source gas supplying valve is firstly closed after the source gas is supplied to the reactor 150 is marked with x3. During the process, the source gas supplying valve is repetitively opened and closed, thus the internal pressure of the reactor increases or decreases showing pulse type variation within a pressure range between point x2 and point x3. The variation of the internal pressure of the vaporizer 130 depends on whether or not the buffer unit 140 exists.

As shown in FIG. 2, in the case (a) where the buffer unit 140 of the deposition apparatus is not included, the internal pressure variation (the difference between the pressure at x2 and the pressure at x3) of the internal pressure of the vaporizer 130 is large during the process, but like the deposition apparatus according to the embodiment of the present invention, in the case (b) where the buffer unit 140 is included, the internal pressure variation (the difference between the pressure at x2 and the pressure at x3) of the internal pressure of the vaporizer 130 is small and the pressure is constant to thereby stably supply the source gas.

The reason for this is that in the case where the source gas supplying valve is closed, thus, the source gas is not supplied to the reactor 150, the source gas discharged from the vaporizer 130 is stored in the buffer unit 140 to serve as a buffer role with respect to the pressure variation. Accordingly, in the case of the deposition apparatus according to the embodiment of the present invention, it is possible to constantly maintain the pressure of the vaporizer 130.

Next, in the deposition apparatus including four reaction spaces RC1, RC2, RC3, and RC4, a silicon oxide film (SiO₂) is deposited by using an SiH_{2(NR}₂)₂ source and the uniformity of the deposited thin film is measured with respect to the case (a) where the buffer 140 is not included and the case (b) where the buffer unit 140 is included. In the experimental example, all other conditions are the same except for whether or not the buffer unit 140 is included.

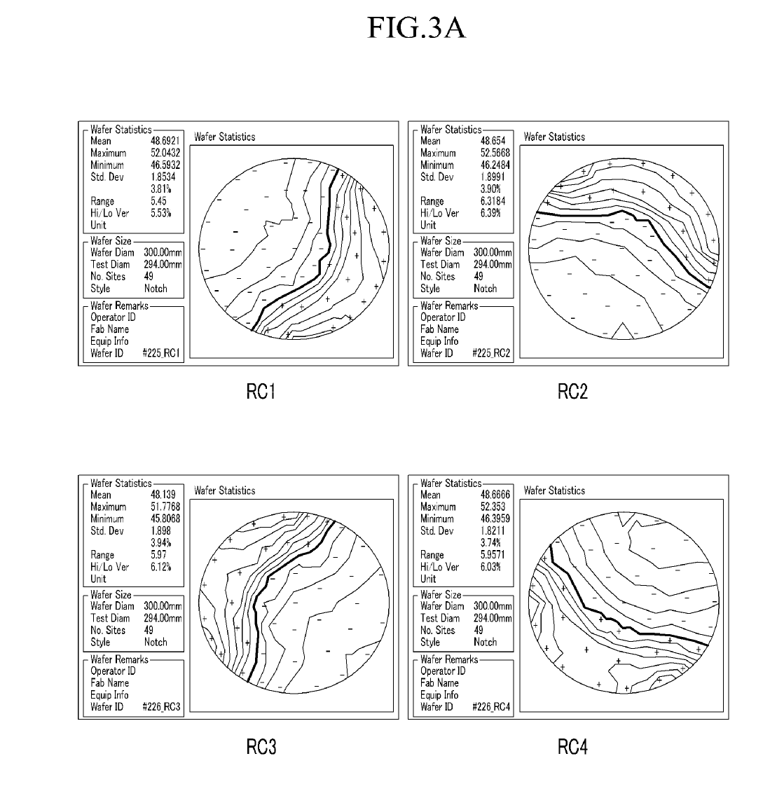

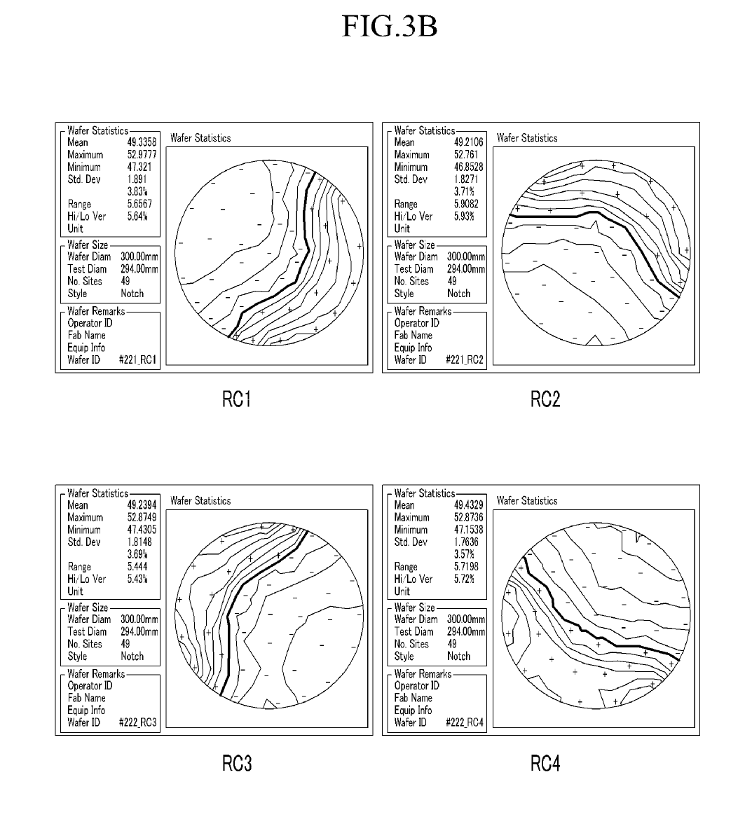

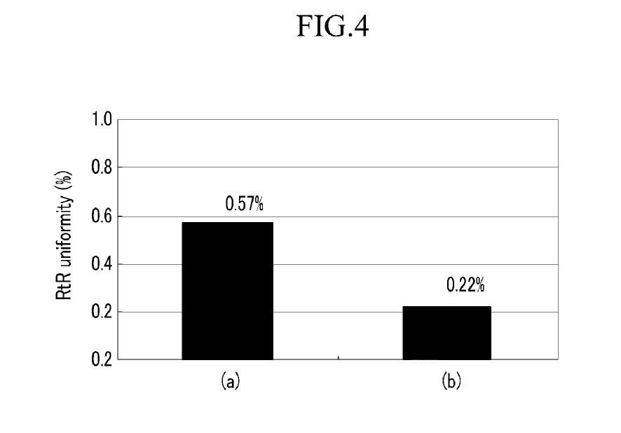

First, the uniformity of the deposited thin film is measured for each of the plurality of reaction spaces and the result is shown in FIGS. 3A and 3B and Table 1 and the uniformity of the deposited thin film is compared for each reaction space and the result is shown in FIG. 4. FIGS. 3A and 3B are graphs showing a thickness for each position of a deposited thin film according an experimental example of the present invention and FIG. 4 is a graph showing a relative difference of thickness uniformity for each reaction space of a thin film deposited according an embodiment of the present invention. FIG. 3A shows the case (a) where the buffer unit 140 is not included and FIG. 3B shows the case (b) where the buffer unit 140 is included.

Referring to FIGS. 3A and 3B and Table 1, in comparison with the case (a) where the buffer unit 140 is not included, while like the deposition apparatus according to the embodiment of the present invention, in the case (b) where the buffer unit 140 is included, the average thickness of the silicon oxide films deposited in the reaction spaces RC1, RC2, RC3, and RC4 is larger and a difference in uniformity is small, thus, the thickness variation per reactors is smaller. Like this, as described in the embodiment of the present invention, when the deposition apparatus includes the buffer unit 140, the source gas is constantly and stably supplied to each reaction space. Therefore, the deposition efficiency of the thin film increases and a process reproducibility is improved which means films deposited in a plurality of reaction spaces have small thickness deviation among them.

TABLE 1

| Reaction Space | | RC1 | RC2 | RC3 | RC4 |
|---|---|---|---|---|---|
| Case (a) | Average | 48.69 | 48.65 | 48.14 | 48.67 |
| | thickness (Å) | | | | |
| | Uniformity (%) | 5.53 | 6.39 | 6.12 | 6.03 |
| Case (b) | Average | 49.34 | 49.21 | 49.23 | 49.43 |
| | thickness (Å) | | | | |
| | Uniformity (%) | 5.64 | 5.93 | 5.43 | 5.72 |

Next, referring to FIG. 4, in comparison with the case (a) where the buffer unit 140 of the deposition apparatus is not included, in the case (b) where the buffer unit 140 is included like the deposition apparatus according to the embodiment of the present invention, the thickness deviation for each reaction space of the silicon oxide films deposited in the reaction spaces RC1, RC2, RC3, and RC4 is smaller. Specifically, in the case (a) where the buffer unit 140 of the deposition apparatus is not included, the film uniformity deviation for each reaction space of the thin films deposited in the reaction spaces RC1, RC2, RC3, and RC4 is approximately 0.57%, but in the case (b) including the buffer unit 140 like the deposition apparatus according to the embodiment of the present invention is approximately 0.22%. Like this, as described in the embodiment of the present invention, when the deposition apparatus includes the buffer unit 140, the source gas is uniformly and stably supplied to the reaction spaces. Therefore, the uniformity deviation of the thin films deposited in the plurality of reaction spaces decreases and the thin films having the same uniformity are deposited.

As described above, the deposition apparatus according to the embodiment of the present invention includes the buffer unit disposed between the vaporizer and the source supplying valve to constantly maintain the internal pressure of the vaporizer. Therefore, the amount of the source gas can be controlled so as to stably supply the same amount of source gas to the reactor, thereby depositing a thin film having improved uniformity.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A deposition apparatus, comprising:
a reactor;
a liquid source unit storing a liquid source of source gas supplied to the reactor;
a liquid source flow controller controlling the flow of the source gas supplied to the reactor;
a vaporizer vaporizing the liquid source supplied from the liquid source flow controller; and
a buffer unit disposed between the reactor and the vaporizer.

2. The deposition apparatus of claim 1, wherein:
the reactor includes a plurality of reaction spaces.

3. The deposition apparatus of claim 2, further comprising:
a source supplying valve disposed between the buffer unit and the reactor.

4. The deposition apparatus of claim 3, wherein:
the source gas is supplied from the vaporizer to the reactor when the source supplying valve is opened.

5. The deposition apparatus of claim 4, wherein:
the source gas discharged from the vaporizer is stored in the buffer unit when the source supplying valve is closed.

6. The deposition apparatus of claim 1, further comprising:
a source supplying valve disposed between the buffer unit and the reactor.

7. The deposition apparatus of claim 6, wherein:
the source gas is supplied from the vaporizer to the reactor when the source supplying valve is opened.

8. The deposition apparatus of claim 6, wherein:
the source gas discharged from the vaporizer is stored in the buffer unit when the source supplying valve is closed.

9. The deposition apparatus of claim 1, wherein:
the variation of the internal pressure of the vaporizer is small after the source gas starts to be supplied to the vaporizer.
